(19) United States
(12) Patent Application Publication
(10) Pub. No.: US 2013/0277010 A1
(43) Pub. Date: Oct. 24, 2013

(54) HEAT DISSIPATING APPARATUS WITH AIR DUCT

(71) Applicant: CHIH-HAO LIN, Tu-Cheng (TW)

(72) Inventor: CHIH-HAO LIN, Tu-Cheng (TW)

(73) Assignee: HON HAI PRECISION INDUSTRY CO., LTD., Tu-Cheng (TW)

(21) Appl. No.: 13/465,044

(22) Filed: May 7, 2012

(30) Foreign Application Priority Data
Apr. 19, 2012 (TW) 101113965

(51) Int. Cl. H05K 5/02; H05K 7/20; F24F 13/02

(52) U.S. Cl. 165/80.2; 454/241; 165/104.33

(57) ABSTRACT

A heat dissipating apparatus in an electrical device includes a air duct. The air duct includes an air inlet and an air outlet. A plurality of ventilation members are attached to the air inlet and the air outlet thereof. Each ventilation member defines a number of ventilation holes of a certain size calculated to keep EMI out. A coated layer formed on an inner surface of the air duct to shield electromagnetic waves which may be generated by the electrical components of the device.

### BACKGROUND

1. Technical Field

The disclosure relates to heat dissipating apparatus and, particularly, to a heat dissipating apparatus with an air duct for guiding airflow and for shielding against electromagnetic interference (EMI).

2. Description of Related Art

Components of electronic devices, such as central processing units (CPUs), memory cards, and south bridge chips, generate a great deal of heat. The heat needs to be dissipated immediately to ensure the continued proper function of the electronic devices. Cooling fans are often provided to generate airflow and air ducts are provided to guide the airflow. However, if the air duct is made of plastic it cannot shield against EMI.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an isometric, exploded view of an embodiment of a heat dissipating apparatus, wherein the heat dissipating apparatus includes an air duct.

FIG. 2 is an inverted, enlarged view of the air duct of FIG. 1.

FIG. 3 is an assembled, isometric view of the heat dissipating apparatus of FIG. 1.

FIG. 4 is a sectional view of the heat dissipating apparatus of FIG. 3, taken along the line IV-IV.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

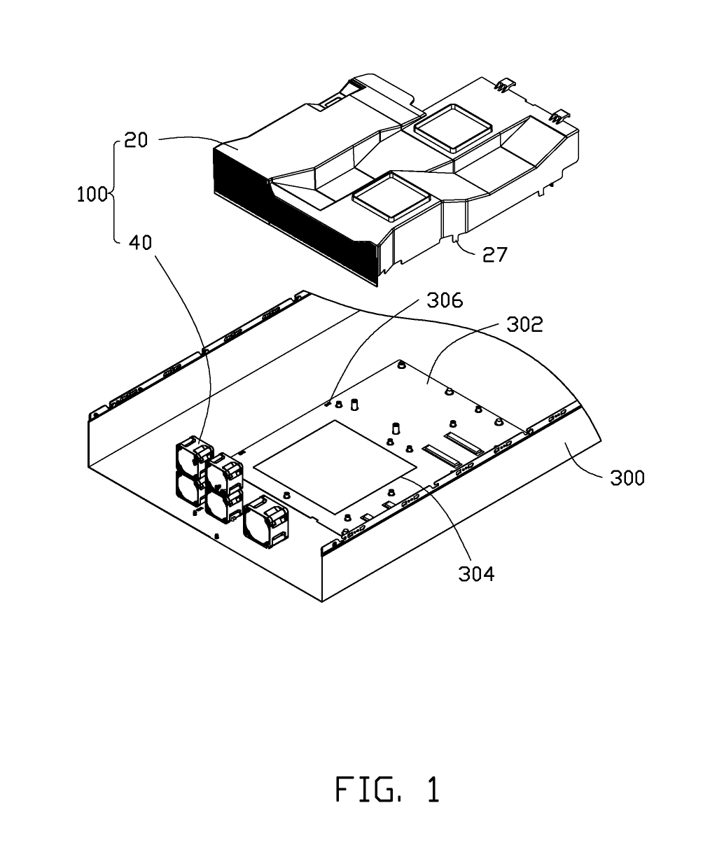

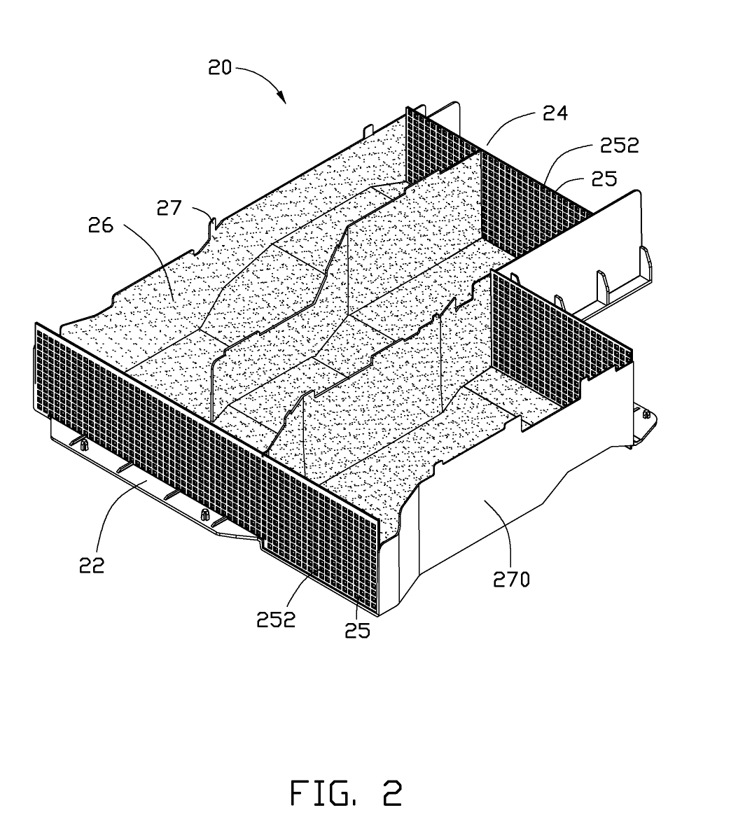

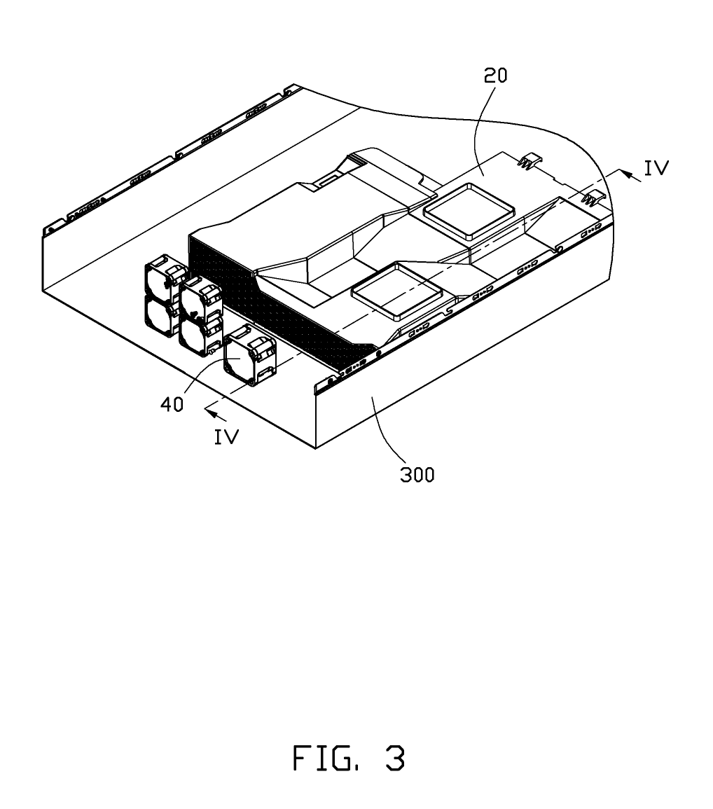

Referring to FIGS. 1 to 3, an embodiment of a heat dissipating apparatus 100 for cooling a plurality of components 304 of a motherboard 302 is shown. The motherboard 302 is mounted in the electronic device 300. There is a plurality of latching holes 306 on opposite sides of the motherboard 302. The heat dissipating apparatus 100 includes an air duct 20, and a plurality of fans 40 located and secured in the electronic device 300 so as to face the components 304.

The air duct 20 is made of plastic and includes an air inlet 22 at a first end and two air outlets 24 at a second end opposite to the air inlet 22. A plurality of parallel dividing plates 270 is set between the air inlet 22 and the air outlets 24 to form a plurality of airways. A plurality of latches 27 extend down from a bottom of the dividing plates 270. Ventilation members 25 are attached to the air inlet 22 and to the air outlets 25. Each ventilation member 25 defines a plurality of ventilation holes 252. A size of each ventilation holes 252 corresponds to wavelength of electromagnetic waves, such as 5 mm and less. A coated layer 26 is formed on inner surfaces of the air duct 20 and the ventilation member 25. The layer 26 is made of electromagnetic interference (EMI) shielding material by a vacuum sputtering plating process, using copper, aluminum, or steel.

In assembly, the latches 27 of the air duct 20 are inserted into the latching holes 306 of the motherboard 302. The fans 40 are aligned with the air inlet 22, and the components 304 find themselves received in the air duct 20.

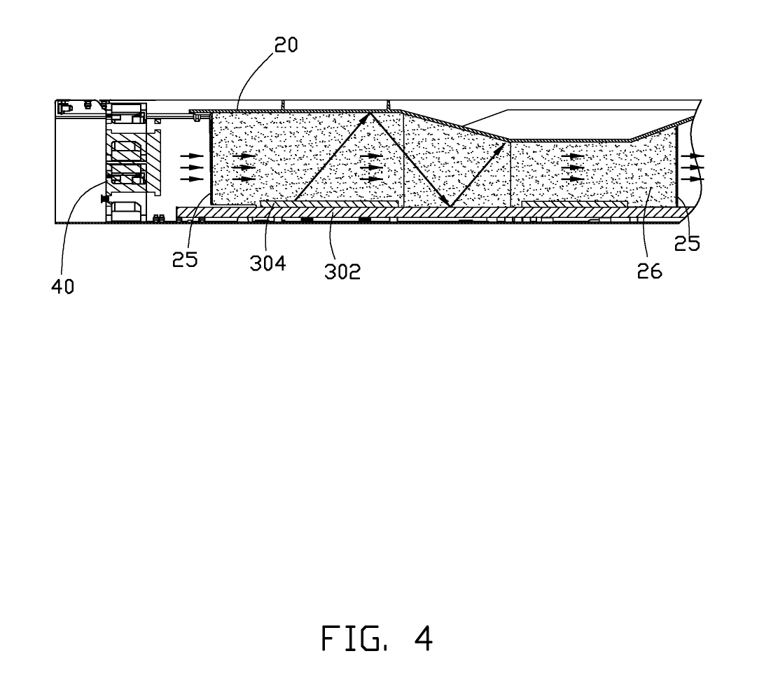

Referring to FIG. 4, in use, the fans 40 introduce air, from the air inlet 22 to the air outlet 24, to cool the components 304 on the motherboard 302. At the same time, any electromagnetic waves generated by the components 304 are shielded by the layer 26. The ventilation members 25 with ventilation holes 252 not only prevent electromagnetic waves generated by the components 304 from being transmitted out, but also prevent electromagnetic waves outside of the air duct 20 from entering and interfering with the operation of the components 304.

It is to be understood, however, that even though numerous characteristics and advantages of certain embodiments have been set forth in the foregoing description, together with details of the structures and functions of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. An air duct, comprising:
an air inlet;
an air outlet;
a plurality of ventilation members respectively attached to the air inlet and the air outlet, each ventilation member defining a plurality of ventilation holes; and
a layer formed on an inner surface of the air duct to shield electromagnetic waves.

2. The air duct of claim 1, wherein the layer is made of electromagnetic interference (EMI) shielding material.

3. The air duct of claim 2, wherein the EMI shielding material is copper.

4. The air duct of claim 1, wherein the layer is formed on the air duct by vacuum sputtering plating.

5. The air duct of claim 1, wherein a size of each ventilation hole is less than 5 mm.

6. A heat dissipating apparatus for cooling a plurality of components of a motherboard, the heat dissipating apparatus comprising:
a fan aligned with the components;
a plastic air duct attached to the motherboard and covering the components, the air duct comprising an air inlet, an air outlet, and a plurality of ventilation members respectively attached to the air inlet and the air outlet, wherein each ventilation member defines a plurality of ventilation holes; and
a layer formed on an inner surface of the air duct to shield electromagnetic waves.

7. The heat dissipating apparatus of claim 6, wherein the layer is made of electromagnetic interference (EMI) shielding material.

8. The heat dissipating apparatus of claim 7, wherein the EMI shielding material is aluminum.

9. The heat dissipating apparatus of claim 6, wherein a size of each ventilation hole is less than 5 mm.
